(19) United States
(12) Patent Application Publication
(10) Pub. No.: US 2026/0247594 A1
(43) Pub. Date: Aug. 20, 2026

(54) Semiconductor layout pattern and manufacturing method thereof

(71) Applicant: UNITED MICROELECTRONICS CORP., Hsin-Chu City (TW)

(72) Inventors: Chun-Hsien Huang, Tainan City (TW); Yu-Tse Kuo, Tainan City (TW); Shou-Wan Huang, Hsinchu City (TW); Shu-Ru Wang, Taichung City (TW); Meng-Ping Chuang, Hsinchu City (TW); Chun-Yen Tseng, Tainan City (TW)

(73) Assignee: UNITED MICROELECTRONICS CORP., Hsin-Chu City (TW)

(21) Appl. No.: 19/075,808

(22) Filed: Mar. 11, 2025

(30) Foreign Application Priority Data
Feb. 19, 2025 (TW) 114106036

(51) Int. Cl. H10B 10/00; G11C 15/04

(52) U.S. Cl. CPC H10B 10/12; G11C 15/04

(57) ABSTRACT

invention provides a semiconductor layout pattern, the semiconductor layout pattern includes a substrate, wherein the substrate includes a plurality of ternary content addressable memory (TCAM) cells, and wherein the layouts of at least two TCAM cells are mirror symmetrical to each other along a symmetry axis. Each TCAM cell comprises a plurality of transistors, and the substrate includes a plurality of fin structures arranged along a Y direction and a plurality of gate structures arranged along an X direction. Among the plurality of gate structures, there is a first gate structure connected to a search line SLB and a second gate structure not connected to the search line SLB, wherein the first gate structure is arranged in parallel with the second gate structure, the first gate structure does not overlap with the symmetry axis, and the second gate structure overlaps with the symmetry axis.

### BACKGROUND OF THE INVENTION

### 1. Field of the Invention

The present invention relates to the field of semiconductors, particularly to a layout pattern for a content addressable memory (CAM) and a method of manufacturing the same.

### 2. Description of the Prior Art

Generally, when performing digital data operations, the volume of data to be processed is substantial. In certain applications, such as network routers, stored data requires frequent dynamic updates and cannot be pre-sorted, making real-time data query processing challenging. To efficiently accelerate the search speed for such large, randomly stored data, content addressable memory (CAM) has been adopted to solve various search-related issues. A content addressable memory (also known as associative memory) functions like a massive lookup table, capable of identifying the address of data matching an input keyword. This is achieved through CAM's specialized hardware architecture, which enables simultaneous comparison of the search keyword with all data stored in the CAM, outputting the address of the data that matches the input keyword. This address can then be used to retrieve data associated with the keyword.

Content addressable memories include binary content addressable memory (BCAM) and ternary content addressable memory (TCAM). In BCAM, each bit has two states, 0 or 1, whereas in TCAM, each bit has three states: 0, 1, and a “don't care” state. This third state in TCAM enables both exact match searches and fuzzy match searches.

### SUMMARY OF THE INVENTION

The present invention provides a semiconductor layout pattern comprising a substrate, wherein the substrate includes a plurality of ternary content addressable memory (TCAM) cells, and wherein the layouts of at least two TCAM cells are mirror symmetrical to each other along a symmetry axis. Each TCAM cell comprises a plurality of transistors, and the substrate includes a plurality of fin structures arranged along a Y direction and a plurality of gate structures arranged along an X direction. A portion of these gate structures crosses the fin structures and forms the plurality of transistors of the TCAM cell. Among the plurality of gate structures, there is a first gate structure connected to a search line SLB and a second gate structure not connected to the search line SLB, wherein the first gate structure is arranged in parallel with the second gate structure, the first gate structure does not overlap with the symmetry axis, and the second gate structure overlaps with the symmetry axis.

The present invention further provides a method of manufacturing a semiconductor layout pattern, comprising providing a substrate and forming a plurality of ternary content addressable memory (TCAM) cells on the substrate, wherein the layouts of at least two TCAM cells are mirror symmetrical to each other along a symmetry axis. Each TCAM cell comprises a plurality of transistors, and the substrate includes a plurality of fin structures arranged along a Y direction and a plurality of gate structures arranged along an X direction. A portion of these gate structures crosses the fin structures and forms the plurality of transistors of the TCAM cell. Among the plurality of gate structures, there is a first gate structure connected to a search line SLB and a second gate structure not connected to the search line SLB, wherein the first gate structure is arranged in parallel with the second gate structure, the first gate structure does not overlap with the symmetry axis, and the second gate structure overlaps with the symmetry axis.

A feature of the present invention lies in that when two TCAM cells are arranged on a substrate, directly dividing the gate structures at the boundary between the two TCAM cells using a continuous elongated cutting pattern tends to cause issues with uneven pattern density. In order to solve this issue, the cutting regions at the boundary between the two TCAM cells in the present invention are segmented into multiple sections arranged in a staggered manner, such as in a diamond-like shape. This results in a more uniform distribution of the cut gate structures, which improves the overall quality of the semiconductor device. Additionally, the present invention connects the first metal layer, which is prone to coupling effects, to a voltage source via an upper contact plug to prevent coupling effects. Furthermore, in some embodiments of the present invention, dummy fin structures are formed alongside the fin structures to enhance the pattern uniformity of the overall layout.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

To facilitate understanding, the following description may be read in conjunction with the drawings and their detailed descriptions. Specific embodiments of the present invention are illustrated in detail through the embodiments described herein and corresponding drawings to explain the operational principles of these embodiments. Additionally, for clarity, the features in the drawings may not be drawn to actual scale; certain features in some drawings may be intentionally enlarged or reduced in size.

FIG. 1 illustrates a circuit pattern of a ternary content addressable memory (TCAM) according to a first embodiment of the present invention.

FIG. 2 illustrates a layout pattern of a single ternary content addressable memory cell according to the first embodiment of the present invention.

FIG. 3 illustrates a layout pattern of two adjacent ternary content addressable memory cells according to the first embodiment of the present invention.

FIG. 4, FIG. 5, and FIG. 6 illustrate layout patterns of two adjacent ternary content addressable memory cells according to a second embodiment of the present invention.

FIG. 7 illustrates a cross-sectional view along the section line B-B′ in FIG. 6, emphasizing the relationship between contact plugs and the first metal layer.

FIG. 8 illustrates a cross-sectional view along the section line A-A′ in FIG. 4, emphasizing the relationship between the substrate, fin structures, and dummy fin structures.

### DETAILED DESCRIPTION

Although specific configurations and arrangements are discussed herein, it should be understood that these are provided for illustrative purposes only. Persons skilled in the relevant art will recognize that other configurations and arrangements may be employed without departing from the spirit and scope of the present disclosure. It will be apparent to those skilled in the relevant art that the disclosure can also be applied to various other applications.

It should be noted that references in the specification to “one embodiment,” “an embodiment,” “an exemplary embodiment,” “some embodiments,” and the like indicate that the described embodiment may include specific features, structures, or characteristics, but not every embodiment necessarily includes these specific features, structures, or characteristics. Moreover, such terms do not necessarily refer to the same embodiment. Furthermore, when a specific feature, structure, or characteristic is described in connection with an embodiment, it is within the knowledge of those skilled in the relevant art to implement such feature, structure, or characteristic in conjunction with other embodiments, whether explicitly described or not.

Typically, terms may be understood at least in part based on their usage in context. For example, the term “one or more” as used herein may, depending at least in part on the context, describe any feature, structure, or characteristic in a singular sense or describe a plurality of features, structures, or characteristics in a combined sense. Similarly, terms such as “a,” “an,” or “the” may again be understood to convey a singular usage or a plural usage, depending at least in part on the context. Additionally, the term “based on” may be understood as not necessarily conveying an exclusive set of factors and may instead allow for the existence of additional factors not explicitly described, depending at least in part on the context.

It should be readily understood that the meanings of “on,” “above,” and “over” in the present disclosure should be interpreted in the broadest sense, such that “on” not only means “directly on” something but also includes the meaning of being on something with intervening features or layers, and “above” or “over” not only means being above or over something but also includes the meaning of being above or over something without intervening features or layers (i.e., directly on something).

Furthermore, for ease of description, spatially relative terms such as “beneath,” “below,” “lower,” “above,” “upper,” and the like may be used, as illustrated in the drawings, to describe the relationship of one element or feature to another element(s) or feature(s). In addition to the orientations depicted in the drawings, these spatially relative terms are intended to encompass different orientations of the device in use or operation. The device may be otherwise oriented (rotated 90 degrees or at other orientations), and the spatially relative descriptors used herein may be interpreted accordingly.

As used herein, the term “substrate” refers to a material onto which subsequent layers of material are added. The substrate itself may be patterned, and materials added on top of the substrate may be patterned or remain unpatterned. Additionally, the substrate may include a variety of semiconductor materials, such as silicon, germanium, gallium arsenide, indium phosphide, etc. Alternatively, the substrate may be made of a non-conductive material, such as glass, plastic, or a sapphire wafer.

As used herein, the term “layer” refers to a portion of material that includes a region with a thickness. A layer may extend over the entirety of an underlying or overlying structure or may have an extent less than that of the underlying or overlying structure. Furthermore, a layer may be a region of a uniform or non-uniform continuous structure with a thickness less than that of the continuous structure. For example, a layer may be located between the top and bottom surfaces of a continuous structure or between any pair of horizontal planes therein. A layer may extend horizontally, vertically, and/or along a tapered surface. A substrate may be a layer, may include one or more layers, and/or may have one or more layers above and/or below it. A layer may include multiple layers. For example, an interconnect layer may include one or more conductor and contact layers (in which contacts, interconnect lines, and/or vias are formed) and one or more dielectric layers.

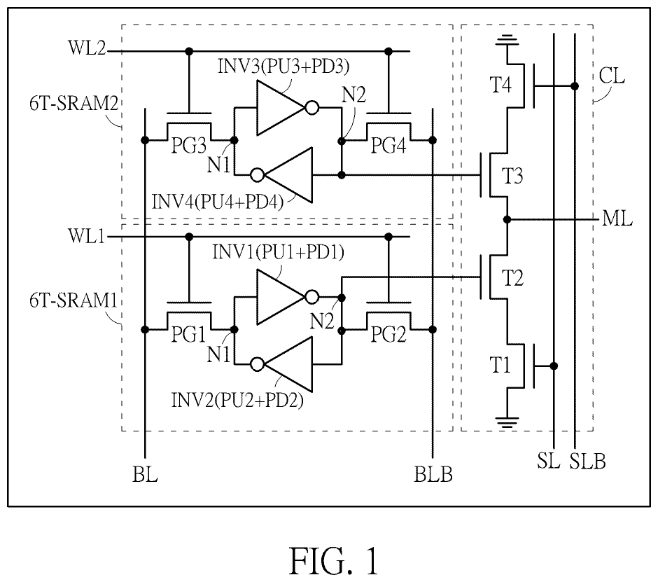

In this embodiment, a ternary content addressable memory (TCAM) is disclosed, wherein the TCAM comprises two six-transistor static random access memories (6T-SRAMs), each composed of six transistors, and a comparison logic circuit composed of four transistors. More specifically, referring to FIG. 1, FIG. 1 illustrates a circuit pattern of a ternary content addressable memory according to a first embodiment of the present invention. As shown in FIG. 1, a TCAM of the present invention is composed of two six-transistor cells (6T-SRAM1 and 6T-SRAM2) and a comparison logic circuit CL. The 6T-SRAM1 cell includes a first pull-up transistor PU1, a second pull-up transistor PU2, a first pull-down transistor PD1, a second pull-down transistor PD2, a first pass gate transistor PG1, and a second pass gate transistor PG2. The 6T-SRAM2 cell includes a third pull-up transistor PU3, a fourth pull-up transistor PU4, a third pull-down transistor PD3, a fourth pull-down transistor PD4, a third pass gate transistor PG3, and a fourth pass gate transistor PG4. The comparison logic circuit CL includes a first transistor T1 and a second transistor T2 connected in series, as well as a third transistor T3 and a fourth transistor T4 connected in series. The first pull-up transistor PU1 and the first pull-down transistor PD1 form a first inverter INV1, the second pull-up transistor PU2 and the second pull-down transistor PD2 form a second inverter INV2, and the first inverter INV1 and the second inverter INV2 constitute a latch circuit, enabling data to be latched at storage nodes N1 and N2. Similarly, the third pull-up transistor PU3 and the third pull-down transistor PD3 form a third inverter INV3, the fourth pull-up transistor PU4 and the fourth pull-down transistor PD4 form a fourth inverter INV4, and the third inverter INV3 and the fourth inverter INV4 constitute a latch circuit, enabling data to be latched at storage nodes N1 and N2.

Taking the 6T-SRAM1 cell as an example, the first pull-up transistor PU1, the second pull-up transistor PU2, the first pull-down transistor PD1, the second pull-down transistor PD2, the first pass gate transistor PG1, and the second pass gate transistor PG2 collectively form a six-transistor static random access memory (6T-SRAM). Additionally, the first pull-up transistor PU1 and the second pull-up transistor PU2 serve as active loads, which may also be replaced with general resistors as pull-up elements, resulting in a four-transistor static random access memory (4T-SRAM). In this embodiment, a source region of each of the first pull-up transistor PU1 and the second pull-up transistor PU2 is electrically connected to a voltage source Vcc (not shown), and a source region of each of the first pull-down transistor PD1 and the second pull-down transistor PD2 is electrically connected to a voltage source Vss (not shown). The 6T-SRAM2 cell has similar features and connections as the 6T-SRAM1 cell described above, as shown in FIG. 1, and thus will not be repeated here.

Generally, the first pull-up transistor PU1, the second pull-up transistor PU2, the third pull-up transistor PU3, and the fourth pull-up transistor PU4 of a 6T-SRAM cell are composed of P-type metal oxide semiconductor (PMOS) transistors, while the first pull-down transistor PD1, the second pull-down transistor PD2, the third pull-down transistor PD3, the fourth pull-down transistor PD4, the first pass gate transistor PG1, the second pass gate transistor PG2, the third pass gate transistor PG3, and the fourth pass gate transistor PG4 are composed of N-type metal oxide semiconductor (NMOS) transistors.

Taking the 6T-SRAM1 cell as an example, at the storage node N1, the gates of the first pull-down transistor PD1 and the first pull-up transistor PU1, as well as the drains of the second pull-down transistor PD2, the second pull-up transistor PU2, and the first pass gate transistor PG1, are electrically connected to each other. Similarly, at the storage node N2, the gates of the second pull-down transistor PD2 and the second pull-up transistor PU2, as well as the drains of the first pull-down transistor PD1, the first pull-up transistor PU1, and the first pass gate transistor PG1, are electrically connected to each other. The 6T-SRAM2 cell has similar features and connections as the 6T-SRAM1 cell described above, as shown in FIG. 1, and thus will not be repeated here. The gates of the first pass gate transistor PG1 and the second pass gate transistor PG2 in the 6T-SRAM1 cell are coupled to a word line WL1, while the gates of the first pass gate transistor PG1 and the second pass gate transistor PG2 in the 6T-SRAM2 cell are coupled to a word line WL 2. The sources of the first pass gate transistor PG1 and the second pass gate transistor PG2 are coupled to corresponding bit lines BLB and BL, respectively.

As shown in FIG. 1, in this embodiment, the gate of the second transistor T2 is connected to the storage node N2 of the 6T-SRAM, meaning that the gate of the second transistor T2 is connected to the gate of the second pull-up transistor PU2 and the gate of the second pull-down transistor PD2. The second transistor T2 is connected in series with the first transistor T1, such that the drain of the second transistor T2 is connected to the source of the first transistor T1. The drain of the first transistor T1 is connected to a voltage source (e.g., Vss), the gate of the first transistor T1 is connected to a search line SLB, and the source of the second transistor T2 is connected to a match line ML.

On the other hand, the connections of the third transistor T3 and the fourth transistor T4 are similar and symmetrical to those of the first transistor T1 and the second transistor T2, respectively. The gate of the third transistor T3 is connected to the storage node N2 of the 6T-SRAM2, meaning that the gate of the third transistor T3 is connected to the gate of the fourth pull-up transistor PU4 and the gate of the fourth pull-down transistor PD4. The fourth transistor T4 is connected in series with the third transistor T3, such that the drain of the fourth transistor T4 is connected to the source of the third transistor T3. The drain of the fourth transistor T4 is connected to a voltage source (e.g., Vss), the gate of the fourth transistor T4 is connected to a search line SL, and the source of the third transistor T3 is connected to the match line ML.

The 6T-SRAM described above serves as a signal storage cell in the ternary content addressable memory, while the first transistor T1, the second transistor T2, the third transistor T3, and the fourth transistor T4 connected to the 6T-SRAM function as the comparison logic circuit of the ternary content addressable memory. In other words, in this embodiment, a single ternary content addressable memory is composed of two 6T-SRAMs and four additional transistors.

In actual operation, the match line ML can be pre-charged to a high potential, and then high or low potentials can be applied to the search lines SL and SLB to turn on or turn off the first transistor T1 and the fourth transistor T4, thereby comparing the signals on the search lines SL and SLB with the signals originally stored in the 6T-SRAM. For example, a high potential can be defined as signal 1, and a low potential can be defined as signal 0. Depending on usage requirements, the signals on the search lines SL and SLB can be set to (0, 1), (1, 0), or (0, 0), where the signals (0, 1) or (1, 0) are compared with the signal at the storage node N1 of the 6T-SRAM. If the comparison result matches, the electrical signal on the match line ML remains at a high potential; if the comparison result does not match, the electrical signal on the match line ML drops from high potential to low potential. Additionally, the signal (0, 0) represents a “don't care” state, enabling fuzzy matching. The above circuit configuration constitutes the ternary content addressable memory (TCAM) described in the present invention. Other principles related to content addressable memory, logic comparison methods, and similar technologies are well-known in the art and will not be elaborated further in this section.

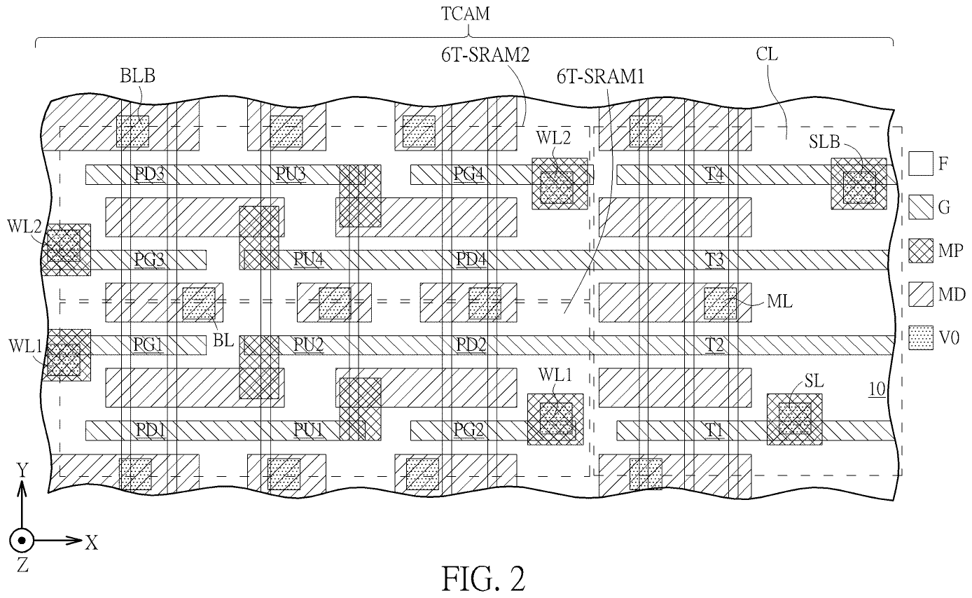

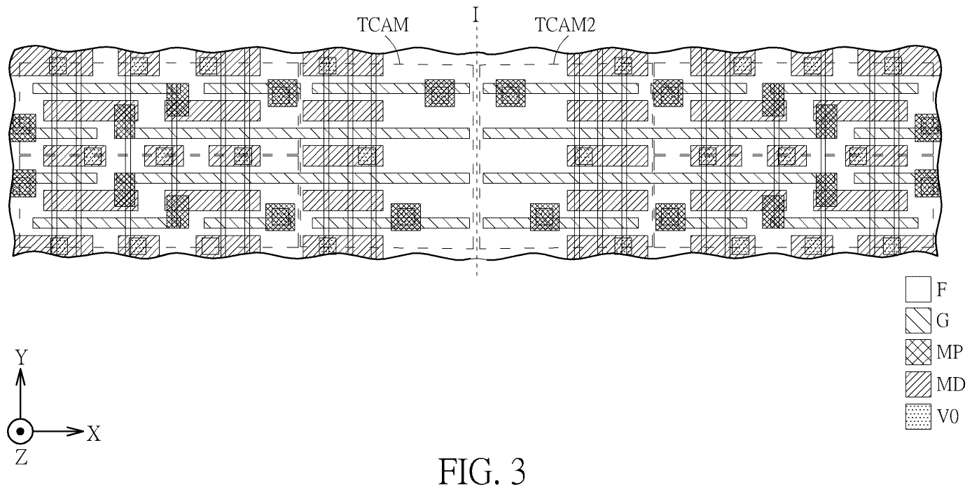

FIG. 2 illustrates a layout pattern of a single ternary content addressable memory cell according to the first embodiment of the present invention. As shown in FIG. 2, to form a ternary content addressable memory cell in each region, a plurality of fin structures F, a plurality of gate structures G (e.g., polysilicon gates, but not limited thereto), and a plurality of conductive layers are formed on a substrate 10. In FIG. 2, the conductive layer overlapping with the gate structures G is defined as MP, while the conductive layer not overlapping with the gate structures G is defined as MD. The conductive layers MP and MD may be made of the same material, such as metals including tungsten, cobalt, copper, aluminum, gold, silver, etc., but not limited thereto. Both the conductive layers MP and MD serve the function of connecting elements. Thus, in some embodiments, the conductive layers MP and MD may be regarded as a single layer structure. Additionally, contact plugs V0 are included to connect the gate structures G or the conductive layers MP/MD to other signal sources, such as wires in other layers, bit lines BL/BLB, word lines WL1/WL2, search lines SL/SLB, match line ML, voltage sources Vcc/Vss, etc.

In some embodiments of the present invention, the fin structures F may also be replaced by diffusion regions; however, the following description will continue to use fin structures F as an example. The gate structures G cross over the fin structures F and combine to form the transistors described above, including the first pull-up transistor PU1, the second pull-up transistor PU2, the third pull-up transistor PU3, the fourth pull-up transistor PU4, the first pull-down transistor PD1, the second pull-down transistor PD2, the third pull-down transistor PD3, the fourth pull-down transistor PD4, the first pass gate transistor PG1, the second pass gate transistor PG2, the third pass gate transistor PG3, the fourth pass gate transistor PG4, the first transistor T1, the second transistor T2, the third transistor T3, and the fourth transistor T4. These transistors can be electrically connected to various signal sources, such as bit lines BL/BLB, word lines WL1/WL2, search lines SL/SLB, match line ML, etc., through subsequently formed metal wires or contact structures. For clarity in the drawings, FIG. 2 and the layout diagrams of various embodiments of the present invention directly label the names of the transistors or the connected signal sources at corresponding positions in the layout diagram to indicate that a specific transistor is formed at that position or that the position is connected to a specific signal source.

When two or more ternary content addressable memory cells (TCAMs) are arranged adjacently, reference may be made to FIGS. 2 and 3. FIG. 3 illustrates a layout pattern of two adjacent ternary content addressable memory cells according to the first embodiment of the present invention. The left half of FIG. 3 includes the same ternary content addressable memory cell TCAM as shown in FIG. 2, while the right half includes another ternary content addressable memory cell TCAM2, wherein the TCAM and TCAM2 cells are mirror symmetrical to each other along a symmetry axis I. The TCAM and TCAM2 cells have substantially symmetrical circuit patterns. For simplicity, these symmetrical components will not be repeatedly described.

As shown in FIG. 3, the TCAM and TCAM2 cells are arranged side by side, but the gate structures G at the symmetry axis I are cut. As a result, the TCAM and TCAM2 cells are electrically insulated from each other and can be regarded as two independent components. More specifically, after the gate structure G fabrication process, a plurality of continuous elongated gate structures are formed. At this point, these continuous elongated structures can be cut into multiple separated gate structure segments through, for example, an etching process, thereby separating the TCAM and TCAM2 cells.

However, the applicant has found that in the aforementioned gate-cutting step, cutting multiple gate structures G at the position overlapping with the symmetry axis I (i.e., along the Y direction) introduces two issues. One issue is that the cutting pattern extends along the longitudinal direction (Y direction) and cuts multiple gate structures G. Due to the long length of the cutting pattern in the Y direction, its width in the X direction must also maintain a certain value. Otherwise, if the aspect ratio of the cutting pattern is too high, the cutting pattern may break during exposure, leading to incomplete cutting of the gate structures G. The other issue is that when all gate structures G between two adjacent TCAM cells are cut along the symmetry axis I, it easily results in uneven pattern density, affecting the quality of subsequent components.

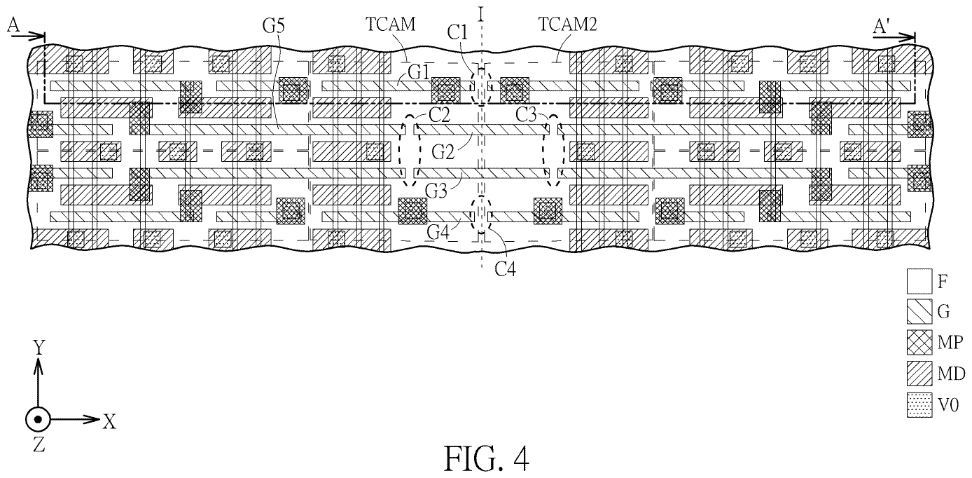

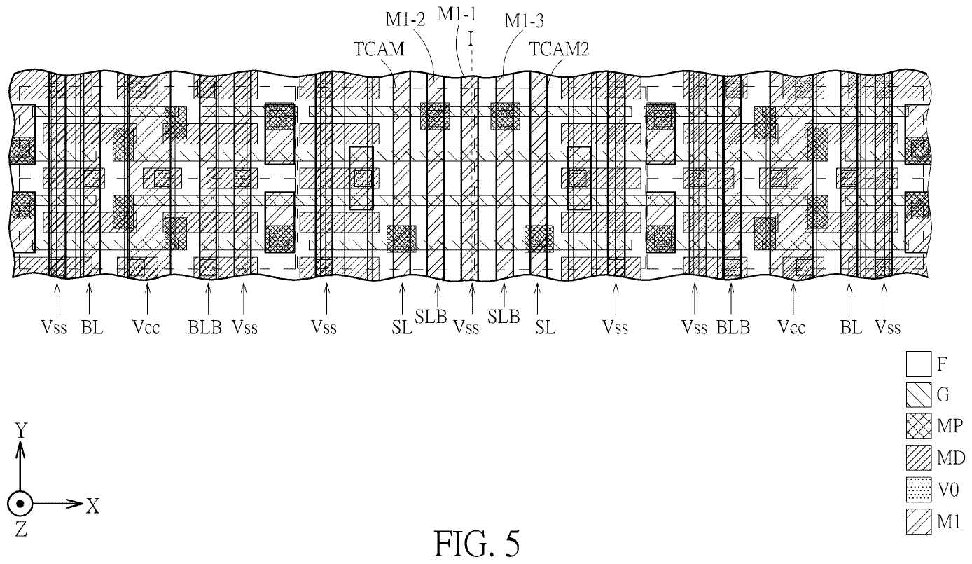

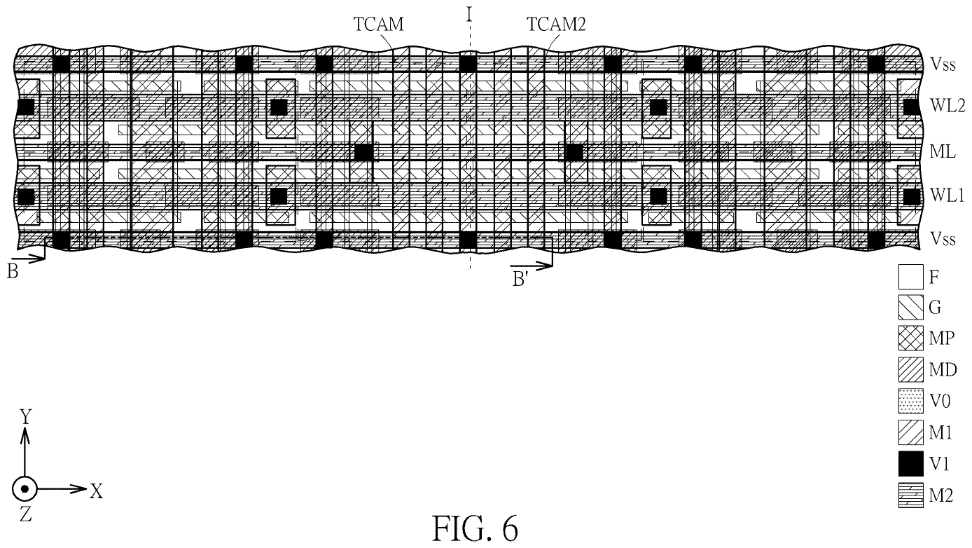

To solve these two issues, other embodiments of the present invention provide an improved layout pattern for ternary content addressable memory cells and a method of manufacturing the same, as detailed in FIGS. 4 to 8 below. The circuit diagram remains the same as in the above embodiment and can be referenced in FIG. 1. Hereinafter, different embodiments of the present invention will be described. For simplicity, the explanation will focus on the differences between the embodiments, without repeating the identical aspects. Additionally, identical components across the embodiments of the present invention are labeled with the same reference numerals to facilitate comparison between embodiments.

FIGS. 4, 5, and 6 illustrate layout patterns of two adjacent ternary content addressable memory cells according to a second embodiment of the present invention. As shown in FIG. 4, this embodiment also includes two adjacently arranged TCAM cells (labeled as TCAM and TCAM2), which are mirror symmetrical to each other along the symmetry axis I. The difference from the above embodiment is that not all gate structures G at the symmetry axis I between the TCAM and TCAM2 cells are cut. Instead, some gate structures G are cut at the symmetry axis I, while others are not cut at the symmetry axis I. More specifically, as shown in FIG. 4, among the plurality of gate structures G, gate structures G1, G2, G3, and G4 can be defined. All of the gate structures G1 to G4 belong to the gate structures G. Wherein the gate structures G1 and G4 are connected to the search lines SL/SLB via contact plugs V0, while the gate structures G2 and G3 are not connected to other components and may be regarded as dummy gate structures. In this embodiment, the gate structures G1, G2, G3, and G4 partially overlap each other in the Y direction. Here, the gate structures G1 and G4 do not overlap with the symmetry axis I, while the gate structures G2 and G3 are not cut at the symmetry axis I and thus overlap with the symmetry axis I. In other words, the difference from the above embodiment is that, during the gate structure cutting step, not all gate structures G overlapping with the symmetry axis I are cut. Instead, some gate structures G overlapping with the symmetry axis I are cut in a staggered manner, while others are not cut at the symmetry axis I.

Further, referring to the cutting regions C1, C2, C3, and C4 outlined with dashed lines in FIG. 4, these cutting regions C1 to C4 represent the areas where the gate structures G are cut. In other words, the gate structures G within the cutting regions C1 to C4 are removed. As seen in FIG. 4, the four adjacent cutting regions C1 to C4 are arranged in a staggered manner resembling a diamond shape, resulting in the cut edges of the gate structures G being distributed in a similar diamond-like pattern.

In this embodiment, since the cutting regions C1 to C4 are arranged in a diamond-shaped distribution, the aspect ratio of each cutting region C1 to C4 is smaller compared to the elongated cutting region extending along the entire symmetry axis I in the embodiment of FIG. 3. This allows the width of each cutting region C1 to C4 to be reduced accordingly, mitigating the risk of incomplete exposure due to an excessively high aspect ratio. Therefore, the gate structures G can be surely cut. Furthermore, since the cutting regions C1 to C4 are distributed more evenly, the density uniformity of the overall semiconductor layout pattern is also improved.

Next, referring to FIGS. 5 and 6, after forming the aforementioned fin structures F, the gate structures G, the conductive layers MP and MD, and the contact plugs V0, subsequent layers such as a first metal layer M1, a plurality of contact plugs V1, and a second metal layer M2 are formed stacked thereon. Here, the first metal layer M1 and the second metal layer M2 may connect different components within the same layer (the XY plane), while the contact plugs V0 and V1 are primarily used to connect components between different layers in the vertical direction (perpendicular to the XY plane). For clarity, FIGS. 5 and 6 label the signal sources connected to the metal wires next to the first metal layer M1 and the second metal layer M2, such as bit lines BL/BLB, word lines WL1/WL2, search lines SL/SLB, match line ML, voltage sources Vcc/Vss, etc.

The materials of the first metal layer M1, the second metal layer M2, the contact plugs V0, and the contact plugs V1 may include highly conductive metals such as tungsten, cobalt, copper, aluminum, gold, silver, etc., but not limited thereto. To simplify the mask pattern design, as shown in FIGS. 5 and 6, the first metal layer M1 formed in FIG. 5 includes a plurality of metal patterns, most of which extend along the Y direction, while the second metal layer M2 in FIG. 6 includes a plurality of metal patterns, most of which extend along the X direction. It should be understood that, although this embodiment illustrates pattern layers such as the first metal layer M1 and the second metal layer M2, in some embodiments, the semiconductor layout pattern may include additional stacked metal layers and metal plugs, such as a third metal layer M3 (not shown), a fourth metal layer M4 (not shown), a plurality of contact plugs V2 (not shown), a plurality of contact plugs V3 (not shown), etc., which are also within the scope of the present invention.

Notably, referring to FIG. 5, the first metal layer M1 includes a plurality of metal patterns extending along the Y direction. The metal pattern overlapping with the symmetry axis I is defined as a first metal line M1-1, and the metal patterns adjacent to the left and right of the first metal line M1-1 are defined as a second metal line M1-2 and a third metal line M1-3, respectively. In this embodiment, the first metal line M1-1 is not connected to the underlying contact plug V0, but the second metal line M1-2 and the third metal line M1-3 are both connected to the underlying contact plugs V0. Consequently, when the circuit is activated, the low-potential first metal line M1-1 is positioned between the high-potential second metal line M1-2 and third metal line M1-3. The applicant has found that this configuration is prone to coupling effects. Specifically, high-potential metal lines generate an electric field that affects low-potential metal lines, causing signal interference issues such as noise.

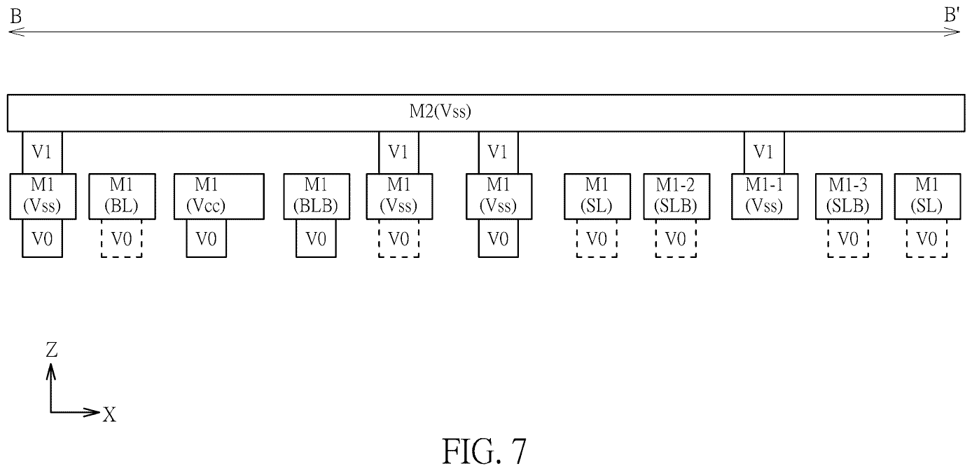

Another feature of the present invention is that, to solve the coupling effect described above, in this embodiment, the first metal line M1-1 is connected to the second metal layer M2 via an upper contact plug V1 and then electrically connect to the voltage source Vss, while the first metal line M1-1 is not connected to the contact plug V0. Reference may be made to FIGS. 6 and 7 together, where FIG. 7 illustrates a cross-sectional view along the section line B-B′ in FIG. 6. To clearly illustrate the features of this embodiment, FIG. 7 primarily depicts the relationship between the contact plugs V0, the first metal layer M1, the contact plugs V1, and the second metal layer M2, with other components omitted. Additionally, some contact plugs V0 shown in dashed lines in FIG. 7 are located below the first metal layer M1, indicating that while these contact plugs V0 do not pass through the section direction B-B′, they are positioned outside the section line B-B′ and are electrically connected to the first metal layer M1. As seen in FIG. 7, the first metal line M1-1 is located between the second metal line M1-2 and the third metal line M1-3, where the second metal line M1-2 and the third metal line M1-3 are both connected to the underlying contact plugs V0 to the search line SLB. The area directly beneath the first metal line M1-1 does not include a contact plug V0; instead, it is electrically connected to the second metal layer M2 via the upper contact plug V1 and electrically connect to the voltage source Vss.

In summary, in this embodiment, one approach to solving the coupling issue is to ground the first metal line M1-1 or connect it to a fixed voltage source (e.g., Vss). However, since the second metal line M1-2 and the third metal line M1-3 on either side of the first metal line M1-1 are already connected to the contact plugs V0, connecting the first metal line M1-1 to the voltage source Vss via an underlying contact plug V0 would require additional space. Therefore, in this embodiment, the first metal line M1-1 is electrically connected to the voltage source Vss via the upper contact plug V1, effectively resolving the coupling effect without requiring additional space.

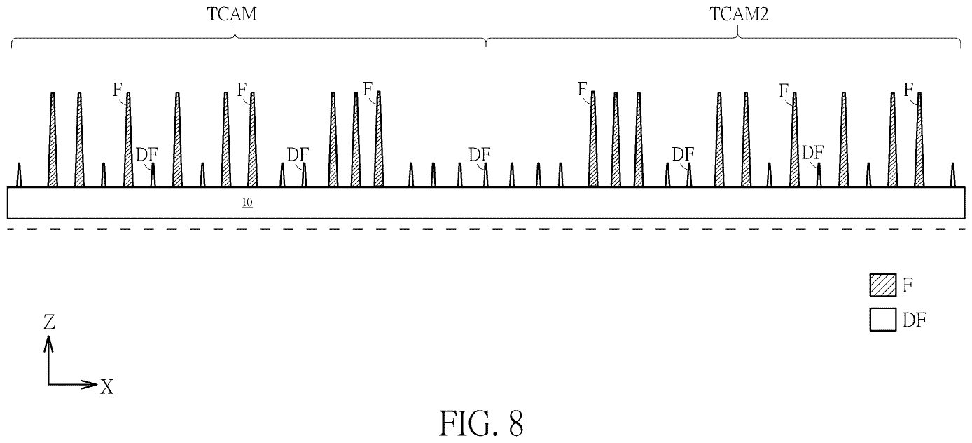

Additionally, another feature of the present invention is illustrated in FIG. 8. FIG. 8 shows a cross-sectional view along the section line A-A′ in FIG. 4, emphasizing the relationship between the substrate, the fin structures, and the dummy fin structures for clarity, with other components omitted. As shown in FIG. 8, when forming the fin structures, to avoid uneven pattern density in the semiconductor layout (such as higher pattern density in regions with fin structures and lower pattern density in regions without fin structures), in some embodiments of the present invention, multiple dummy fin structures DF are formed on the substrate 10 simultaneously with the fin structures F. In a cross-sectional view, the width and height of the dummy fin structures DF are preferably smaller than those of the fin structures F. The purpose of forming the dummy fin structures DF in the present invention is to achieve a more uniform overall pattern and avoid the aforementioned uneven pattern density issue. In subsequent steps, the dummy fin structures DF may remain on the substrate 10, meaning that the gate structures G cross not only the fin structures F but also the dummy fin structures DF. Alternatively, in other embodiments, the dummy fin structures DF may be removed, which is also within the scope of the present invention.

Based on the above specification and drawings, the present invention provides a semiconductor layout pattern comprising a substrate 10, wherein the substrate 10 includes a plurality of ternary content addressable memory (TCAM) cells, and wherein the layouts of at least two TCAM cells (TCAM and TCAM2) are mirror symmetrical to each other along a symmetry axis I. Each TCAM cell comprises a plurality of transistors, and the substrate 10 includes a plurality of fin structures F arranged along a Y direction and a plurality of gate structures G arranged along an X direction. A portion of these gate structures G crosses the fin structures F and forms the plurality of transistors of the TCAM cell. Among the plurality of gate structures G, there is a first gate structure G1 connected to a search line SLB and a second gate structure G2 not connected to the search line SLB, wherein the first gate structure G1 is arranged in parallel with the second gate structure G2, the first gate structure G1 does not overlap with the symmetry axis I, and the second gate structure G2 overlaps with the symmetry axis I.

In some embodiments of the present invention, an extending direction of the symmetry axis I is parallel to an extending direction of each fin structure (both extending along the Y direction), and the extending direction of the symmetry axis I is perpendicular to an extending direction of each gate structure G (the gate structures G extend along the X direction).

In some embodiments of the present invention, the plurality of transistors in each TCAM cell includes two six-transistor layout patterns (6T-SRAM1 and 6T-SRAM2) and a comparison logic circuit CL, wherein each six-transistor layout pattern includes: a first pull-up transistor PU1 and a first pull-down transistor PD1 forming a first inverter INV1, a second pull-up transistor PU2 and a second pull-down transistor PD2 forming a second inverter INV2, and a first pass gate transistor PG1 and a second pass gate transistor PG2 connecting the first inverter and the second inverter. The comparison logic circuit CL includes a first transistor T1 and a second transistor T2 connected in series, as well as a third transistor T3 and a fourth transistor T4 connected in series, wherein the gate structure included in the second transistor T2 is connected to the gate structure of the second pull-down transistor PD2.

In some embodiments of the present invention, the first gate structure G1 crosses a portion of the fin structures F and constitutes the first transistor T1, while the second gate structure G2 does not cross the fin structures.

In some embodiments of the present invention, the plurality of gate structures G further includes a third gate structure (e.g., gate structure G5 in FIG. 4), which crosses the fin structures F and constitutes the second transistor T2, wherein the third gate structure G5 is aligned with the second gate structure G2 in the X direction.

In some embodiments of the present invention, the layout pattern includes a first metal layer M1 comprising a plurality of metal lines, wherein a first metal line M1-1 included in the first metal layer M1 overlaps with the symmetry axis, and a second metal line M1-2 included in the first metal layer M1 is electrically connected to the first gate structure G1 via a zeroth-layer contact plug V0. In a cross-sectional view, the zeroth-layer contact plug V0 is located below the second metal line M1-2.

In some embodiments of the present invention, the first metal line M1-1 is electrically connected to a second metal layer M2 via a first-layer contact plug V1 and is connected to a voltage source Vss.

In some embodiments of the present invention, in a cross-sectional view, the first-layer contact plug V1 is located above the first metal line M1-1, and no contact plug V0 is present directly beneath the first metal line M1-1 (as shown in FIG. 7).

In some embodiments of the present invention, the first metal line M1-1 is parallel to the second metal line M1-2, the first metal line M1-1 is adjacent to the second metal line M1-2, and an extending direction of the first metal line M1-1 is parallel to an extending direction of the symmetry axis I.

In some embodiments of the present invention, the layout further includes a plurality of dummy fin structures DF located on the substrate 10, with a portion of the dummy fin structures DF positioned between the fin structures F, wherein the width and height of the dummy fin structures DF are smaller than the width and height of the fin structures F.

The present invention further provides a method of manufacturing a semiconductor layout pattern, comprising providing a substrate 10 and forming a plurality of ternary content addressable memory (TCAM) cells on the substrate 10, wherein the layouts of at least two TCAM cells are mirror symmetrical to each other along a symmetry axis I. Each TCAM cell comprises a plurality of transistors, and the substrate 10 includes a plurality of fin structures F arranged along a Y direction and a plurality of gate structures G arranged along an X direction. A portion of these gate structures G crosses the fin structures F and forms the plurality of transistors of the TCAM cell. Among the plurality of gate structures G, there is a first gate structure G1 connected to a search line SLB and a second gate structure G2 not connected to the search line SLB, wherein the first gate structure G1 is arranged in parallel with the second gate structure G2, the first gate structure G1 does not overlap with the symmetry axis I, and the second gate structure G2 overlaps with the symmetry axis I.

In some embodiments of the present invention, an extending direction of the symmetry axis I is parallel to an extending direction of each fin structure (both extending along the Y direction), and the extending direction of the symmetry axis I is perpendicular to an extending direction of each gate structure G (the gate structures G extend along the X direction).

In some embodiments of the present invention, the plurality of transistors in each TCAM cell includes two six-transistor layout patterns (6T-SRAM1 and 6T-SRAM2) and a comparison logic circuit CL, wherein each six-transistor layout pattern includes: a first pull-up transistor PU1 and a first pull-down transistor PD1 forming a first inverter INV1, a second pull-up transistor PU2 and a second pull-down transistor PD2 forming a second inverter INV2, and a first pass gate transistor PG1 and a second pass gate transistor PG2 connecting the first inverter and the second inverter. The comparison logic circuit CL includes a first transistor T1 and a second transistor T2 connected in series, as well as a third transistor T3 and a fourth transistor T4 connected in series, wherein the gate structure included in the second transistor T2 is connected to the gate structure of the second pull-down transistor PD2.

In some embodiments of the present invention, the first gate structure G1 crosses a portion of the fin structures F and constitutes the first transistor T1, while the second gate structure G2 does not cross the fin structures.

In some embodiments of the present invention, the plurality of gate structures G further includes a third gate structure (e.g., gate structure G5 in FIG. 4), which crosses the fin structures F and constitutes the second transistor T2, wherein the third gate structure G5 is aligned with the second gate structure G2 in the X direction.

In some embodiments of the present invention, the method further includes forming a first metal layer M1 comprising a plurality of metal lines, wherein a first metal line M1-1 included in the first metal layer M1 overlaps with the symmetry axis, and a second metal line M1-2 included in the first metal layer M1 is electrically connected to the first gate structure G1 via a zeroth-layer contact plug V0. In a cross-sectional view, the zeroth-layer contact plug V0 is located below the second metal line M1-2.

In some embodiments of the present invention, the first metal line M1-1 is electrically connected to a second metal layer M2 via a first-layer contact plug V1 and is connected to a voltage source Vss.

In some embodiments of the present invention, in a cross-sectional view, the first-layer contact plug V1 is located above the first metal line M1-1, and no contact plug V0 is present directly beneath the first metal line M1-1 (as shown in FIG. 7).

In some embodiments of the present invention, the first metal line M1-1 is parallel to the second metal line M1-2, the first metal line M1-1 is adjacent to the second metal line M1-2, and an extending direction of the first metal line M1-1 is parallel to an extending direction of the symmetry axis I.

In some embodiments of the present invention, the method further includes forming a plurality of dummy fin structures DF on the substrate 10, with a portion of the dummy fin structures DF positioned between the fin structures F, wherein the width and height of the dummy fin structures DF are smaller than the width and height of the fin structures F.

In summary, a feature of the present invention lies in that when two TCAM cells are arranged on a substrate, directly dividing the gate structures at the boundary between the two TCAM cells using a continuous elongated cutting pattern tends to cause issues with uneven pattern density. In order to solve this issue, the cutting regions at the boundary between the two TCAM cells in the present invention are segmented into multiple sections arranged in a staggered manner, such as in a diamond-like shape. This results in a more uniform distribution of the cut gate structures, which improves the overall quality of the semiconductor device. Additionally, the present invention connects the first metal layer, which is prone to coupling effects, to a voltage source via an upper contact plug to prevent coupling effects. Furthermore, in some embodiments of the present invention, dummy fin structures are formed alongside the fin structures to enhance the pattern uniformity of the overall layout.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor layout pattern, comprising:
a substrate, wherein the substrate includes a plurality of ternary content addressable memory (TCAM) cells, and wherein the layouts of at least two TCAM cells are mirror symmetrical to each other along a symmetry axis;
wherein each TCAM cell comprises a plurality of transistors, and the substrate includes a plurality of fin structures arranged along a Y direction and a plurality of gate structures arranged along an X direction, wherein a portion of the gate structures crosses the fin structures and constitutes the plurality of transistors of the TCAM cell; and
wherein the plurality of gate structures includes a first gate structure connected to a search line SLB and a second gate structure not connected to the search line SLB, wherein the first gate structure is arranged in parallel with the second gate structure, the first gate structure does not overlap with the symmetry axis, and the second gate structure overlaps with the symmetry axis.

2. The semiconductor layout pattern of claim 1, wherein an extending direction of the symmetry axis is parallel to an extending direction of each of the fin structures, and the extending direction of the symmetry axis is perpendicular to an extending direction of each of the gate structures.

3. The semiconductor layout pattern of claim 1, wherein the plurality of transistors in each TCAM cell includes two six-transistor layout patterns and a comparison logic circuit, wherein each six-transistor layout pattern comprising:
a first pull-up transistor PU1 and a first pull-down transistor PD1 forming a first inverter INV1, a second pull-up transistor PU2 and a second pull-down transistor PD2 forming a second inverter INV2, and a first pass gate transistor PG1 and a second pass gate transistor PG2 connecting the first inverter INV1 and the second inverter INV2;
the comparison logic circuit comprises a first transistor T1 and a second transistor T2 connected in series, and a third transistor T3 and a fourth transistor T4 connected in series, wherein the gate structure included in the second transistor T2 is connected to the gate structure included in the second pull-down transistor PD2.

4. The semiconductor layout pattern of claim 3, wherein the first gate structure crosses a portion of the fin structures and constitutes the first transistor T1, and the second gate structure does not cross the fin structures.

5. The semiconductor layout pattern of claim 1, wherein the plurality of gate structures further includes a third gate structure, which crosses the fin structures and constitutes the second transistor T2, wherein the third gate structure is aligned with the second gate structure in the X direction.

6. The semiconductor layout pattern of claim 1, wherein the layout pattern includes a first metal layer M1 comprising a plurality of metal lines, wherein a first metal line included in the first metal layer M1 overlaps with the symmetry axis, and a second metal line included in the first metal layer M1 is electrically connected to the first gate structure via a zero^{th}-layer contact plug V0, wherein, in a cross-sectional view, the zero^{th}-layer contact plug V0 is located below the second metal line.

7. The semiconductor layout pattern of claim 6, wherein the first metal line is electrically connected to a second metal layer M2 via a first-layer contact plug V1 and is connected to a voltage source Vss.

8. The semiconductor layout pattern of claim 7, wherein, in a cross-sectional view, the first-layer contact plug V1 is located above the first metal line, and no contact plug is present directly beneath the first metal line.

9. The semiconductor layout pattern of claim 6, wherein the first metal line is parallel to the second metal line, the first metal line is adjacent to the second metal line, and an extending direction of the first metal line is parallel to an extending direction of the symmetry axis.

10. The semiconductor layout pattern of claim 1, further comprising a plurality of dummy fin structures located on the substrate, wherein a portion of the dummy fin structures is positioned between the fin structures, and the width and height of the dummy fin structures are smaller than the width and height of the fin structures.

11. A method of manufacturing a semiconductor layout pattern, comprising:
providing a substrate;
forming a plurality of ternary content addressable memory (TCAM) cells on the substrate, wherein the layouts of at least two TCAM cells are mirror symmetrical to each other along a symmetry axis;
wherein each TCAM cell comprises a plurality of transistors, and the substrate includes a plurality of fin structures arranged along a Y direction and a plurality of gate structures arranged along an X direction, wherein a portion of the gate structures crosses the fin structures and constitutes the plurality of transistors of the TCAM cell; and
wherein the plurality of gate structures includes a first gate structure connected to a search line SLB and a second gate structure not connected to the search line SLB, wherein the first gate structure is arranged in parallel with the second gate structure, the first gate structure does not overlap with the symmetry axis, and the second gate structure overlaps with the symmetry axis.

12. The method of manufacturing a semiconductor layout pattern of claim 11, wherein an extending direction of the symmetry axis is parallel to an extending direction of each of the fin structures, and the extending direction of the symmetry axis is perpendicular to an extending direction of each of the gate structures.

13. The method of manufacturing a semiconductor layout pattern of claim 11, wherein the plurality of transistors in each TCAM cell includes two six-transistor layout patterns and a comparison logic circuit, wherein each six-transistor layout pattern comprising:
a first pull-up transistor PU1 and a first pull-down transistor PD1 forming a first inverter INV1, a second pull-up transistor PU2 and a second pull-down transistor PD2 forming a second inverter INV2, and a first pass gate transistor PG1 and a second pass gate transistor PG2 connecting the first inverter INV1 and the second inverter INV2;
the comparison logic circuit comprises a first transistor T1 and a second transistor T2 connected in series, and a third transistor T3 and a fourth transistor T4 connected in series, wherein the gate structure included in the second transistor T2 is connected to the gate structure of the second pull-down transistor PD2.

14. The method of manufacturing a semiconductor layout pattern of claim 13, wherein the first gate structure crosses a portion of the fin structures and constitutes the first transistor T1, and the second gate structure does not cross the fin structures.

15. The method of manufacturing a semiconductor layout pattern of claim 11, wherein the plurality of gate structures further includes a third gate structure, which crosses the fin structures and constitutes the second transistor T2, wherein the third gate structure is aligned with the second gate structure in the X direction.

16. The method of manufacturing a semiconductor layout pattern of claim 11, further comprising forming a first metal layer M1 comprising a plurality of metal lines, wherein a first metal line included in the first metal layer M1 overlaps with the symmetry axis, and a second metal line included in the first metal layer M1 is electrically connected to the first gate structure via a zeroth-layer contact plug V0, wherein, in a cross-sectional view, the zeroth-layer contact plug V0 is located below the second metal line.

17. The method of manufacturing a semiconductor layout pattern of claim 16, wherein the first metal line is electrically connected to a second metal layer M2 via a first-layer contact plug V1 and is connected to a voltage source Vss.

18. The method of manufacturing a semiconductor layout pattern of claim 17, wherein, in a cross-sectional view, the first-layer contact plug V1 is located above the first metal line, and no contact plug is present directly beneath the first metal line.

19. The method of manufacturing a semiconductor layout pattern of claim 16, wherein the first metal line is parallel to the second metal line, the first metal line is adjacent to the second metal line, and an extending direction of the first metal line is parallel to an extending direction of the symmetry axis.

20. The method of manufacturing a semiconductor layout pattern of claim 11, further comprising forming a plurality of dummy fin structures on the substrate, wherein a portion of the dummy fin structures is positioned between the fin structures, and the width and height of the dummy fin structures are smaller than the width and height of the fin structures.
